(19) United States
(12) Patent Application Publication
(10) Pub. No.: US 2004/0080001 A1
(43) Pub. Date: Apr. 29, 2004

(54) Complementary integrated circuit and method of manufacturing same

(76) Inventor: Kiyoshi Takeuchi, Tokyo (JP)

Correspondence Address: PATENT GROUP, CHOATE, HALL & STEWART, EXCHANGE PLACE, 53 STATE STREET, BOSTON, MA, 02109, US

(21) Appl. No.: 10/689,331

(22) Filed: Oct. 20, 2003

Related U.S. Application Data
(62) Division of application No. 09/516,073, filed on Mar. 1, 2000.

(30) Foreign Application Priority Data
Mar. 1, 1999 (JP) 11-052323

(51) Int. Cl. H01L 29/76

(52) U.S. Cl. 257/407

(57) ABSTRACT

A complementary integrated circuit comprises: an n-channel element having a gate electrode in which at least a portion contacting a gate insulating film is made of a first metal material having a work function close to the work function of n-type polysilicon; and a p-channel element having a gate electrode in which at least a portion contacting a gate insulating film is made of a second metal material having a work function close to the work function of p-type polysilicon. Preferably, the first metal material consists of a material selected from a group consisting of zirconium and hafnium, and the second metal material consists of a material selected from a group consisting of platinum silicide, iridium silicide, cobalt, nickel, rhodium, palladium, rhenium and gold. Alternatively, the first metal material may consist of a material selected from a group consisting of zirconium and hafnium, and the second metal material may consist of rhenium.

### FIELD OF THE INVENTION

The present invention relates generally to a complementary integrated circuit and a method of manufacturing the same, and more particularly to a complementary MISFET having a plurality of gate electrodes composed of different materials and its manufacturing method.

### BACKGROUND OF THE INVENTION

Complementary integrated circuits, especially complementary MISFET integrated circuits have hitherto widely been known. In such conventional complementary MISFET integrated circuits, for example, n-type polysilicon containing diffused phosphorus has been widely used as a material of gate electrodes.

The n-type polysilicon is advantageous in that it has a high resistance to heat and chemicals, that it is easy to introduce a high-concentration impurity, and that it is capable of forming a good interface with the gate insulating film, for example, it is capable of forming an interface having good adhesion to the gate insulating film. Use of the n-type polysilicon as the gate electrodes may however result in a p-channel FET having a higher threshold value than a desired value. A technique has thus been used for lowering the threshold value of the p-channel FET by means of counter doping. That is, a technique has been used in which, in the p-channel FET, the p-type impurity is introduced only in the vicinity of the surface of the substrate.

Nevertheless, with miniaturization of the integrated circuits themselves, there has been a need to lessen the depth of the counter doping impurity to be introduced in the vicinity of the substrate surface, making it difficult to implement the p-channel FET using the n-type polysilicon gate.

In order to deal with such a problem, in case the gate length is, for example, 0.25 μm or less, a so-called pn gate (or dual gate) configuration is employed in which the n-type polysilicon is used for the gate or gate electrode of the n channel FET, and the p-type polysilicon is used for the gate or gate electrode of the p-channel FET.

Such a pn gate configuration makes use of gate materials suitable respectively for the n-channel type FET and p-channel type FET, it is possible to miniaturize the p-channel FET in particular, as compared with the conventional nn gate (or single gate) configuration which uses only the phosphorus diffused n-type polysilicon as a gate material of both the p-channel FET and the n-channel FET.

It is relatively easy in the pn gate configuration to form two kinds of gate electrodes comprising mutually different gate materials on the same substrate. That is, polysilicon which does not contain impurity is first deposited on a substrate. Thereafter, n-type impurity is introduced only into an n-channel FET region and p-type impurity is introduced only into a p-channel FET region, locally by ion implantation. Thereby, an n-type polysilicon portion and a p-type polysilicon portion can be formed on the substrate.

With reference to the drawings, an explanation will be made on a method of manufacturing a complementary integrated circuit, here a complementary MISFET, having such conventional pn gate configuration. FIGS. 7A through 7D are cross sectional views illustrating in order of process steps a conventional method of manufacturing the complementary integrated circuit. First, as shown in FIG. 7A, a semiconductor layer is formed on an appropriate substrate 1, and an n-well region 203B and a p-well region 203A are formed via a predetermined element isolation region 202. Thereafter, a gate insulating film 207 and a polysilicon film 221 are deposited thereon. Then, as shown in FIG. 7B, the polysilicon film 221 and the gate insulating film 207 are selectively removed by using photolithography and etching, and the like. Thereby, a gate electrode 221A is formed on a p-well region 203A via a gate insulating film 207A, and a gate electrode 221B is formed on an n-well region 203B via a gate insulating film 207B.

Afterward, as illustrated in FIG. 7C, for example, only a region corresponding to the p-channel FET is covered with a photo resist film 231 and n-type impurity 241 is ion implanted only into a region corresponding to the n-channel FET. Thereby, the gate 221A of the n-channel FET is converted to an n-type gate, and n-type source/drain diffusion layers 205A are formed in the p-type well region 203A. Thereafter, the photo resist film 231 is removed. Subsequently, as shown in FIG. 7D, only a region corresponding to the n-channel FET is covered with a newly formed photo resist 232 and p-type impurity 242 is ion implanted only into a region corresponding to the p-channel FET region. Thereby the gate 221B of the p-channel FET is converted to a p-type gate, and p-type source/drain diffusion layers 205B are formed in the n-type well region 203B. Thereafter, the photo resist film 232 is removed. Thus, the above-mentioned pn gate configuration is completed.

By the way, in a complementary MISFET integrated circuit including a combination of two different types of MISFETs, i.e., n-channel type and p-channel type MISFETs, it would be effective to form respective gate electrodes by using different materials for the n-channel FETs and p-channel FETs, in order to achieve miniaturization or fining down and high integration degree of the MISFETs.

The reason is that the work functions, that is, electrical potentials peculiar to materials, of the gate materials suitable for obtaining good characteristics of FET's will be different in the n-channel FET and the p-channel FET and hence that use of a single material as a gate material may make it difficult for the n-channel FET and the p-channel FET to offer good characteristics at the same time.

More concretely, when the gate material suitable for either one of the n-channel FET and the p-channel FET is used, a threshold value of the other becomes too higher than the desired value. In the event of a MISFET having a relatively large size, this deficiency could be overcome by controlling the threshold value by means of the counter doping method. With a progress of a MISFET toward miniaturization, it would however be necessary to extremely lessen the depth of and raise concentration of the distribution of the impurity which is counter doped for controlling the threshold value. Therefore, it becomes difficult to apply the counter doping method thereto.

On the contrary, the pn gate configuration can be a technique for separately using two different gate materials for the n-channel FET and the p-channel FET. However, the conventional pn gate configuration may suffer from a problem that it is difficult to sufficiently increase the n-type or p-type impurity concentration in the gate electrodes made of polysilicon.

More specifically, the impurity is introduced by ion implantation from the top surface of the gate electrode made of polysilicon, and thence moves by diffusion to the underside of the gate electrode made of polysilicon which is in contact with the gate insulating film. It would be limitative to raise the diffusion temperature or extend the diffusion time, since it is necessary to avoid occurrence of a phenomenon that the impurity, especially boron as p-type impurity, penetrates through the gate insulating film.

Therefore, an impurity concentration in the vicinity of the underside of the gate electrode made of polysilicon becomes relatively low, so that, upon an operation of the FETs, a depletion layer may be formed in the vicinity of the underside of the gate electrode made of polysilicon. As a result thereof, the FET gate insulating film may have an increased effective thickness, leading to a deterioration in the performances of the FETs.

Influence of this gate depletion problem becomes severer as the FETs get finer and as the gate insulating films get thinner, and it becomes remarkable especially in case the gate length is approximately 0.1 μm or less.

On the other hand, it may be possible to solve the gate depletion problem by using metals as the gate materials. The metals are not only free from occurrence of the depletion, but also are advantageous in that they often tend to lower the gate resistance when metals are used as a gate material.

It would also be effective to use, as the gate materials, semiconductors which are deposited while doping a high-concentration impurity. By doping the semiconductor during its deposition, impurity of higher concentration can be introduced than by the ion implantation.

When the metallic materials or metal materials are used as the gate materials or the semiconductors deposited while doping an impurity are used as the gate materials, there arises a problem that it is difficult to form two different types of gate electrodes composed of mutually different gate materials on the same substrate.

That is, it is impossible to use the method in which the gates are separately formed of two different gate materials by means of ion implantation as in the conventional pn gate configuration.

In general, with respect to the gate electrodes made of metallic materials, it is more difficult to perform formation of gate electrodes by etching as compared with the case of the gate electrodes made of polysilicon.

### SUMMARY OF THE INVENTION

It is therefore an object of the present invention to overcome the above-mentioned drawbacks of the prior art and to provide a complementary integrated circuit and a manufacturing method thereof in which gate electrodes are fabricated by using different gate materials for the n-channel FET and the p-channel FET and in which the problem of gate depletion can be effectively suppressed.

It is another object of the present invention to provide a complementary integrated circuit and a manufacturing method thereof which makes it possible to easily realize a fine and high-performance complementary MISFET integrated circuit.

It is still another object of the present invention to obviate a difficulty in processing metallic materials and to provide a complementary MISFET integrated circuit which uses different metallic gate materials for the n-channel FET and p-channel FET and a method which enables easily manufacturing of such integrated circuit.

In order to attain the above objects, the present invention employs the following technical configurations.

According to an aspect of the present invention, there is provided an n-channel field effect transistor having a gate electrode in which at least a portion contacting a gate insulating film is made of a metal material having a work function close to the work function of n-type polysilicon.

In this case, it is preferable that the metal material consists of a material selected from a group consisting of zirconium and hafnium.

It is also preferable that at least a portion of the gate electrode in contact with a gate insulating film is made of the metal material, and a portion other than the portion made of the metal material is made of a material having a predetermined low electrical resistivity.

According to another aspect of the present invention, there is provided a p-channel field effect transistor having a gate electrode in which at least a portion contacting a gate insulating film is made of a metal material having a work function close to the work function of p-type polysilicon.

In this case, it is preferable that the metal material consists of a material selected from a group consisting of platinum silicide, iridium silicide, cobalt, nickel, rhodium, palladium, rhenium and gold.

It is also preferable that the metal material consists of rhenium.

It is further preferable that at least a portion of the gate electrode in contact with a gate insulating film is made of the metal material, and a portion other than the portion made of the metal material is made of a material having a predetermined low electrical resistivity.

According to a still another aspect of the present invention, there is provided a complementary integrated circuit comprising: an n-channel element having a gate electrode in which at least a portion contacting a gate insulating film is made of a first metal material having a work function close to the work function of n-type polysilicon; and a p-channel element having a gate electrode in which at least a portion contacting a gate insulating film is made of a second metal material having a work function close to the work function of p-type polysilicon.

In this case, it is preferable that the first metal material consists of a material selected from a group consisting of zirconium and hafnium, and the second metal material consists of a material selected from a group consisting of platinum silicide, iridium silicide, cobalt, nickel, rhodium, palladium, rhenium and gold.

It is also preferable that the first metal material consists of a material selected from a group consisting of zirconium and hafnium, and the second metal material consists of rhenium.

It is further preferable that, in the gate electrode of the n-channel element, at least a portion of the gate electrode in contact with a gate insulating film is made of the first metal material, and a portion other than the portion made of the first metal material is made of a material having a predetermined low electrical resistivity, and wherein, in the gate electrode of the p-channel element, at least a portion of the gate electrode in contact with a gate insulating film is made of the second metal material, and a portion other than the portion made of the second metal material is made of a material having a predetermined low electrical resistivity.

According to still another aspect of the present invention, there is provided a method of manufacturing a complementary integrated circuit, comprising: preparing a semiconductor substrate; forming a region for forming an n-channel element and a region for forming a p-channel element on the semiconductor substrate via an element isolation region; forming a dummy gate electrode in each of the region for forming an n-cannel element and the region for forming a p-channel element; forming n-type diffusion regions in the region for forming an n-channel element and forming p-type diffusion regions in the region for forming a p-channel element; forming an insulating film over the entire surface of the semiconductor substrate; removing the dummy gate formed in one of the region for forming an n-channel element and the region for forming a p-channel element to form a first trench in the insulating film; filling the first trench with a gate electrode material; removing the dummy gate formed in the other of the region for forming an n-channel element and the region for forming a p-channel element to form a second trench in the insulating film; and filling the second trench with a gate electrode material.

In this case, it is preferable that, in the forming n-type diffusion regions in the region for forming an n-channel element and forming p-type diffusion regions in the region for forming a p-channel element, an n-type impurity is ion implanted into the region for forming an n-channel element by using a resist film covering the region for forming a p-channel element and the dummy gate formed in the region for forming an n-channel element as a mask, and a p-type impurity is ion implanted into the region for forming a p-channel element by using a resist film covering the region for forming an n-channel element and the dummy gate formed in the region for forming a p-channel element as a mask.

It is also preferable that, in the forming an insulating film over the entire surface of the semiconductor substrate, the insulating film is formed so as to cover the dummy gate formed in the region for forming an n-channel element and the dummy gate formed in the region for forming a p-channel element; and the method further comprises, after the forming an insulating film over the entire surface of the semiconductor substrate, removing at least a potion of the insulating film to expose upper surfaces of the dummy gate formed in the region for forming an n-channel element and the dummy gate formed in the region for forming a p-channel element.

It is further preferable that the method further comprises, after the removing the dummy gate formed in one of the region for forming an n-channel element and the region for forming a p-channel element to form a first trench in the insulating film, forming a gate insulating film at the bottom portion of the first trench, wherein, in the filling the first trench with a gate electrode material, the first trench is filled with the gate electrode material within the first trench and on the gate insulating film formed at the bottom portion of the first trench, wherein the method further comprises, after the removing the dummy gate formed in the other of the region for forming an n-channel element and the region for forming a p-channel element to form a second trench in the insulating film, forming a gate insulating film at the bottom portion of the second trench, and wherein, in the filling the second trench with a gate electrode material, the second trench is filled with the gate electrode material within the second trench and on the gate insulating film formed at the bottom portion of the second trench.

It is advantageous that, in the filling the first trench with a gate electrode material, a film made of the gate electrode material is formed on whole surface of the semiconductor substrate so as to fill the first trench and is polished to expose the upper surface of the insulating film, and wherein, in the filling the second trench with a gate electrode material, a film made of the gate electrode material is formed on whole surface of the semiconductor substrate so as to fill the second trench and is polished to expose the upper surface of the insulating film.

It is also advantageous that a gate electrode material portion filling a trench formed in the region for forming an n-channel element among the first trench and the second trench comprises a metal material which has a work function close to the work function of n-type polysilicon at least at a bottom portion of the gate electrode material portion, and wherein a gate electrode material portion filling a trench formed in the region for forming a p-channel element among the first trench and the second trench comprises a metal material which has a work function close to the work function of p-type polysilicon at least at a bottom portion of the gate electrode material portion.

It is further advantageous that a gate electrode material portion filling a trench formed in the region for forming an n-channel element among the first trench and the second trench comprises, at least at a bottom portion thereof, a material selected from a group consisting of zirconium and hafnium, and wherein a gate electrode material portion filling a trench formed in the region for forming an p-channel element among the first trench and the second trench comprises, at least at a bottom portion thereof, a material selected from a group consisting of platinum silicide, iridium silicide, cobalt, nickel, rhodium, palladium, rhenium and gold.

It is also preferable that a gate electrode material portion filling a trench formed in the region for forming an n-channel element among the first trench and the second trench comprises, at least at a bottom portion thereof, n-type polysilicon deposited while doping n-type impurity, and wherein a gate electrode material portion filling a trench formed in the region for forming a p-channel element among the first trench and the second trench comprises, at least at a bottom portion thereof, p-type polysilicon deposited while doping p-type impurity.

It is further preferable that a gate electrode material portion filling a trench formed in the region for forming an n-channel element among the first trench and the second trench comprises, at least at a bottom portion thereof, a material having a work function close to the work function of n-type polysilicon and other portion of the gate electrode material portion comprises a material having a predetermined low electrical resistivity, and wherein a gate electrode material portion filling a trench formed in the region for forming a p-channel element among the first trench and the second trench comprises, at least at a bottom portion thereof, a material having a work function close to the work function of p-type polysilicon and other portion of the gate electrode material portion comprises a material having a predetermined low electrical resistivity.

According to still another aspect of the present invention, there is provided a method of manufacturing a complementary integrated circuit, comprising: preparing a semiconductor substrate; forming a region for forming an n-channel element and a region for forming a p-channel element on the semiconductor substrate via an element isolation region; forming an insulating film over the entire surface of the semiconductor substrate; selectively removing the insulating film to form a first trench in the insulating film on one of the region for forming an n-channel element and the region for forming a p-channel element; filling the first trench with a gate electrode material; selectively removing the insulating film to form a second trench in the insulating film on the other of the region for forming an n-channel element and the region for forming a p-channel element; filling the second trench with a gate electrode material; removing the insulating film; forming n-type diffusion regions in the region for forming an n-channel element and forming p-type diffusion regions in the region for forming a p-channel element.

In this case, it is preferable that the method further comprises, after the selectively removing the insulating film to form a first trench in the insulating film on one of the region for forming an n-channel element and the region for forming a p-channel element, forming a gate insulating film at the bottom portion of the first trench, wherein, in the filling the first trench with a gate electrode material, the first trench is filled with the gate electrode material within the first trench and on the gate insulating film formed at the bottom portion of the first trench, wherein the method further comprises, after the selectively removing the insulating film to form a second trench in the insulating film on the other of the region for forming an n-channel element and the region for forming a p-channel element, forming a gate insulating film at the bottom portion of the second trench, and wherein, in the filling the second trench with a gate electrode material, the second trench is filled with the gate electrode material within the second trench and on the gate insulating film formed at the bottom portion of the second trench.

It is also preferable that, in the filling the first trench with a gate electrode material, a film made of the gate electrode material is formed on whole surface of the semiconductor substrate so as to fill the first trench and is polished to expose the upper surface of the insulating film, and wherein, in the filling the second trench with a gate electrode material, a film made of the gate electrode material is formed on whole surface of the semiconductor substrate so as to fill the second trench and is polished to expose the upper surface of the insulating film.

It is further preferable that a gate electrode material portion filling a trench formed in the region for forming an n-channel element among the first trench and the second trench comprises a metal material which has a work function close to the work function of n-type polysilicon at least at a bottom portion of the gate electrode material portion, and wherein a gate electrode material portion filling a trench formed in the region for forming a p-channel element among the first trench and the second trench comprises a metal material which has a work function close to the work function of p-type polysilicon at least at a bottom portion of the gate electrode material portion.

It is advantageous that a gate electrode material portion filling a trench formed in the region for forming an n-channel element among the first trench and the second trench comprises, at least at a bottom portion thereof, a material selected from a group consisting of zirconium and hafnium, and wherein a gate electrode material portion filling a trench formed in the region for forming an p-channel element among the first trench and the second trench comprises, at least at a bottom portion thereof, a material selected from a group consisting of platinum silicide, iridium silicide, cobalt, nickel, rhodium, palladium, rhenium and gold.

It is also advantageous that a gate electrode material portion filling a trench formed in the region for forming an n-channel element among the first trench and the second trench comprises, at least at a bottom portion thereof, n-type polysilicon deposited while doping n-type impurity, and wherein a gate electrode material portion filling a trench formed in the region for forming a p-channel element among the first trench and the second trench comprises, at least at a bottom portion thereof, p-type polysilicon deposited while doping p-type impurity.

It is further advantageous that a gate electrode material portion filling a trench formed in the region for forming an n-channel element among the first trench and the second trench comprises, at least at a bottom portion thereof, a material having a work function close to the work function of n-type polysilicon and other portion of the gate electrode material portion comprises a material having a predetermined low electrical resistivity, and wherein a gate electrode material portion filling a trench formed in the region for forming a p-channel element among the first trench and the second trench comprises, at least at a bottom portion thereof, a material having a work function close to the work function of p-type polysilicon and other portion of the gate electrode material portion comprises a material having a predetermined low electrical resistivity.

According to the complementary integrated circuit and the method of manufacturing the same in accordance with the present invention, it is possible to avoid depletion of the gate, and also, by using the gate materials having work functions suitable respectively for the n-channel element and p-channel element, it becomes possible to implement a fine and high-performance complementary MISFET integrated circuit.

Furthermore, according to the present invention, by using the way of forming the electrodes by abrasion or etch back after filling the opening or trench with the electrode materials, the second gate electrode can be processed and formed without affecting the previously formed first gate electrode. Therefore, it becomes possible to readily form a plurality of different gate electrodes on the same substrate.

Furthermore, since the technique of separately forming the gates of different gate materials by ion implantation is not used, any materials could be selected as the gate materials.

Moreover, since etching is not used to process the gate electrodes, any materials hard to etch could be applied to the gate electrodes, thereby providing a wider selectability of the materials.

### BRIEF DESCRIPTION OF THE DRAWINGS

These and other features, and advantages, of the present invention will be more clearly understood from the following detailed description taken in conjunction with the accompanying drawings, in which like reference numerals designate identical or corresponding parts throughout the figures, and in which:

FIGS. 1A through 1D, FIGS. 2A through 2D, FIGS. 3A through 3D and FIGS. 4A through 4D are schematic cross sectional views illustrating, in order of process steps, cross sectional structures of a complementary integrated circuit during a manufacturing process according to a method of manufacturing such complementary integrated circuit according to an embodiment of the present invention;

FIGS. 5A through 5E and FIGS. 6A through 6D are schematic cross sectional views illustrating, in order of process steps, cross sectional structures of a complementary integrated circuit during a manufacturing process according to a method of manufacturing such complementary integrated circuit according to another embodiment of the present invention; and

FIGS. 7A through 7D are sectional views for explaining an example of the conventional method of manufacturing a complementary integrated circuit.

### DESCRIPTION OF PREFERRED EMBODIMENTS

The present invention will now be described with reference to the drawings which show a specific example of the configuration of a complementary integrated circuit and a method of manufacturing the same in accordance with the present invention.

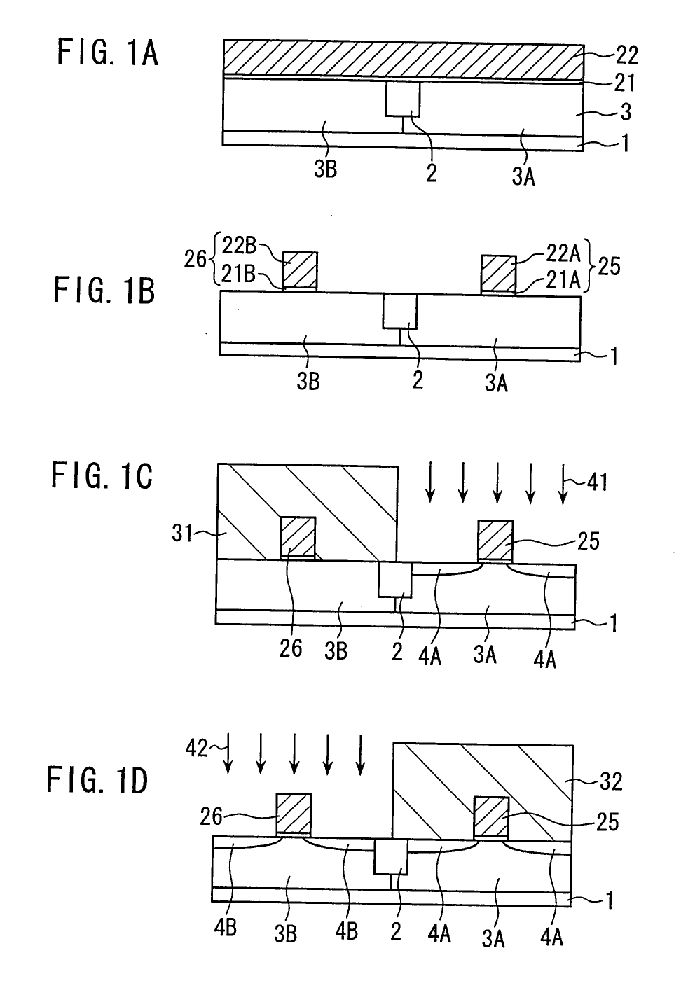

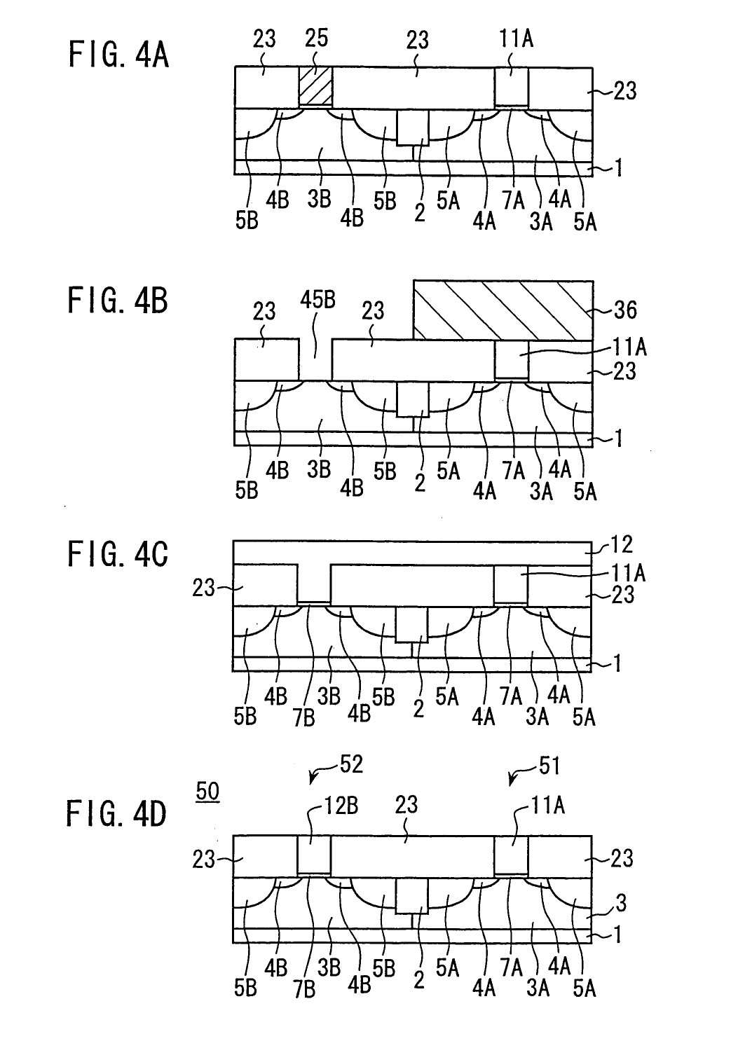

FIG. 4D is a cross sectional view which schematically illustrates a complementary integrated circuit according to an embodiment of the present invention. Also, FIGS. 1A through 1D, FIGS. 2A through 2D, FIGS. 3A through 3D and FIGS. 4A through 4D are schematic cross sectional views illustrating, in order of process steps, a method of manufacturing such complementary integrated circuit.

The complementary integrated circuit 50 according to an embodiment of the present invention and shown in FIG. 4D comprises an n-channel element 51 having a gate electrode 11A made of a first metallic material or metal material selected from a group consisting of zirconium and hafnium, and a p-channel element 52 having a gate electrode 12B made of a second metallic material or metal material selected from a group consisting of platinum silicide, iridium silicide, cobalt, nickel, rhodium, palladium, rhenium and gold.

More specifically, the complementary integrated circuit 50 according to this embodiment comprises, as shown in FIG. 4D, a semiconductor layer 3 formed on an appropriate substrate 1, the semiconductor layer 3 including a p-well region 3A and an n-well region 3B which are formed via a predetermined element isolation region 2.

In the n-channel element 51, the gate electrode 11A of the first metallic material is formed on a part of the surface of the p-well region 3A via a gate insulating film 7A. Also, in the p-well region 3A and on both sides of the gate electrode 11A, diffusion layers 4A and 5A containing predetermined n-type impurities are formed. The diffusion layers 4A and 5A function as source/drain regions having an LDD structure.

Similarly, in the p-channel element 52 the gate electrode 12B of the second metal material is formed on part of the surface of the n-well region 3B via a gate insulting film 7B. Also, in the n-well region 3B and on both sides of the gate electrode 12B, diffusion layers 4B and 5B containing predetermined p-type impurities are formed. The diffusion layers 4B and 5B function as source/drain regions having an LDD structure. Also, the gate electrodes 11A and 12B are buried in an insulating film 23 if necessary. Although not shown in the drawing, it is possible to form an interlayer insulating film on the insulating film 23 and the gate electrodes 11A and 12B, and, via through holes formed in the interlayer insulating film, to electrically couple the gate electrodes 11A and 12B and source/drain regions 5A and 5B with wirings not shown in the drawing.

The second metal material for use in the present invention is preferably rhenium.

In the present invention the semiconductor substrate could also be made of SOI (silicon on insulator) and in such case the p-well region and the n-well region may not necessarily be formed separately especially for forming the n-channel element 51 and the p-channel element 52.

It is necessary in the present invention that the first metal material be one having a work function approximate to the work function of n⁺ polysilicon and that the second metal material have a work function approximate to the work function of p⁺ polysilicon.

As used herein, the work function refers to an electrical potential proper to that material.

Although in the above specific example, whole portions of the gate electrodes 11A and 12B are formed of the first and second metal materials, respectively, the present invention is not limited to such configurations. For instance, the gate electrode 11A constituting the n-channel element 51 may employ a multi-layer structure consisting at least of a lower layer made of the first metal material and being in contact with the gate insulating film 7A, and an upper layer made of a conductive material different from the first metal material and having a low electrical resistivity.

In the same manner, the gate electrode 12B making up the p-channel element 52 may employ a multi-layer structure consisting at least of a lower layer made of the second metal material and being in contact with the gate insulating film 7B, and an upper layer made of a conductive material different from the second metal material and having a low electrical resistivity.

Aluminum, tungsten, titanium, titanium nitride, etc., have hitherto been used as the metal gate materials although they were not most suitable for both nMOSFETs and pMOSFETs, because their work functions are substantially intermediate between those of n⁺ polysilicon and p⁺ polysilicon.

The inventors have found as a result of devoted investigations that zirconium or hafnium are optimum metal materials as the first metal material which has a work function closer to that of n+ polysilicon that is most suitable for nMOSFETs.

In addition to their appropriate work functions, such metal materials have excellent features such as a good chemical stability, a great anticorrosion obtained as a result of formation of a steady oxide layer in the air, and a high resistance to heat.

Since such materials have a disadvantage of high electrical resistivity, it is preferred that a two-layer or multi-layer gate electrode structure be employed which consists of a lower layer being in contact with the gate insulating film and made mainly of the first metal material and an upper layer made of a metal having low resistivity. In this case, it is preferable that a film thickness of the first metal material, that is, zirconium or hafnium is approximately 3 nm or more.

The metal forming the upper layer in the gate electrode 11A is preferably tungsten having a low electrical resistivity and easy to process. Also, depending on the situations, it can be various metal silicides such as titanium silicide and the like which are widely used in the conventional silicon processes.

Furthermore, between the lower layer portion made of the first metal material and the upper layer potion made of tungsten and the like, there is preferably provided with an adhesion layer formed of titanium nitride, tungsten nitride or the like.

It has further been found that platinum silicide, iridium silicide, cobalt, nickel, rhodium, palladium, rhenium, gold, etc. are most suitable as the second metal material having a work function closer to that of p+ polysilicon which is the optimum material for pMOSFETs. In the present invention, one metal material selected from the group of metal materials is used as a material of the gate electrode 12B of the p-channel element 52.

Similar to nMOSFETs, in respect of such metals as well, the gate electrode is preferably of the two-layer or multi-layer structure in which the second metal material is used for the lower layer portion of the gate electrode 12B in contact with the gate insulating film 7B and a metal having low electrical resistivity is used for the upper layer portion thereof.

The present invention will also be effective even in cases where n⁺ polysilicon is used for the gate electrodes of nMOSFETs or where p⁺ polysilicon is used for the gate electrodes of pMOSFETs as in the prior art.

More specifically, use of the manufacturing method in accordance with the present invention mentioned later will allow the gate materials of the nMOSFETs and pMOSFETs to be separately deposited, so that it is possible to introduce n-type or p-type impurities with a high concentration into polysilicon simultaneously with the deposition, in place of introducing impurities into the polysilicon by ion implantation. This process is performed, for example, by depositing polysilicon while doping an impurity by using doping gas, when polysilicn is deposited by a CVD method.

By using such method, it is possible to raise an impurity concentration in the vicinity of the gate insulating film in the gate electrode made of polysilicon as compared with the conventional method, thereby making it possible to restrain the gate depletion.

In such case as well, the multi-layer structure could be employed in order to diminish the resistance of the gate electrode, with the use of n⁺ polysilicon or p⁺ polysilicon only in the lower layer portions in contact with the gate insulating film, and with the use of a conductive material having low electrical resistivity in upper layer portions of gate electrodes.

With reference to the drawings, detailed description will hereinafter be made on the specific example of the complementary integrated circuit and the method of manufacturing the same in accordance with the present invention.

Referring to FIGS. 1A through 1D, FIGS. 2A through 2D, FIGS. 3A through 3D and FIGS. 4A through 4D, there are shown along the manufacturing process cross sections of the complementary MISFET integrated circuit 50 which is a specific example of the present invention.

In this specific example the source/drain diffusion layers are formed previous to the formation of the gate electrodes.

First, as shown in FIG. 1A, the p-well 3A, n-well 3B and element isolation insulating film 2 are formed on a semiconductor layer 3 formed on the semiconductor substrate 1, or on the semiconductor substrate 1 itself, in a conventional manner, after which a protection film 21 and a film 22 are deposited in sequence.

As shown in FIG. 1B, using ordinary photolithography and etching, the protection film 21 and the film 22 are selectively removed, and dummy gates 25 and 26 are formed by leaving portions 21A and 21B of the protection film 21 and portions 22A and 22B of the film 22 only at regions where the gate electrodes are to be formed.

Next, as shown in FIG. 1C, only the p-channel element region is then covered with a photo resist film 31, and n-type impurities 41 are ion implanted into the n-channel element region by using the fummy gate 25 as a mask to form a shallow n-type source/drain diffusion layer 4A in the p-well 3A.

As shown in FIG. 1D, the photo resist film 31 is then stripped off and only the n-channel element region is newly covered with a photo resist film 32, and the p-type impurities 42 are ion implanted into the p-channel element region by using the dummy gate 26 as a mask to form a shallow p-type source/drain diffusion layer 4B in the n-well 3B.

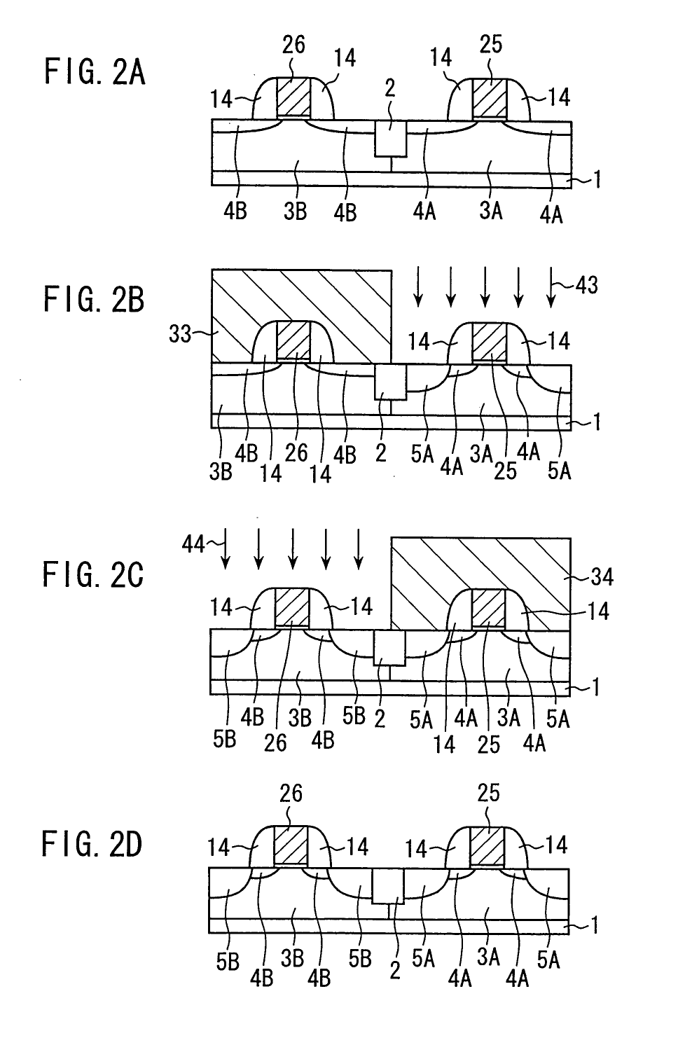

As shown in FIG. 2A, the photo resist film 32 is then stripped off, and side wall insulating film spacers 14 composed of silicon oxide films and the like are formed at the sides of the dummy gates 25 and 26 by an ordinary technique using CVD and etch back.

Next, as shown in FIG. 2B, only the p-channel element region is then covered with a photo resist film 33, and n-type impurities 43 are ion implanted into the n-channel element region by using the dummy gate 25 and the side wall insulating film spacers 14 as a mask to form a deep p-type source/drain diffusion layer 5A in the p-well 3A.

As shown in FIG. 2C, the photo resist film 33 is then stripped off and only the n-channel element region is newly covered with a photo resist film 34, and the p-type impurities 44 are ion implanted into the p-channel element region by using the dummy gate 26 and side wall insulating film spacers 14 as a mask to form a deep p-type source/drain diffusion layer 5B in the n-well 3B.

It is also possible to make an impurity concentration of the source/drain diffusion layers 5A and 5B larger than that of the source/drain diffusion layers 4A and 4B. Then, as shown in FIG. 2D, the resist film 34 is removed.

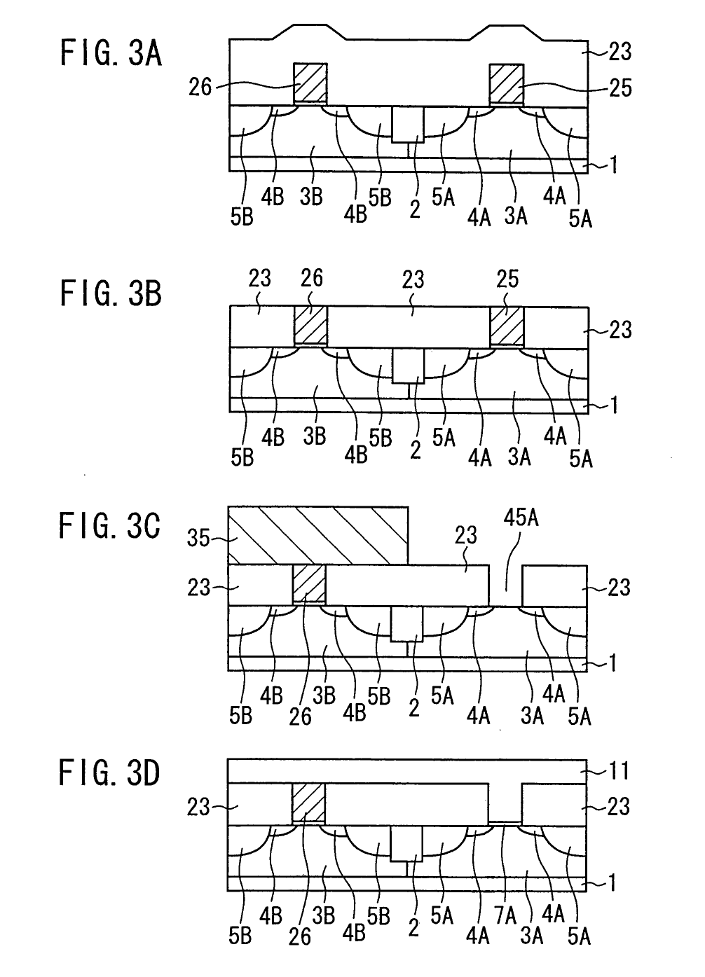

As shown in FIG. 3A, an insulating film 23 made of silicon oxide and the like is then deposited on the overall surface of the substrate. In this embodiment, since the sidewall insulating film spacers 14 and the insulating film 23 are both formed of silicon oxide films, interface portions therebetween are not illustrated in the drawings after FIG. 3A. Then, as shown in FIG. 3B, the upper surface of the insulating film 23 is planarized by ordinary abrasion, polishing or etch back so as to allow the top of the dummy gates 25 and 26 to be exposed.

As shown in FIG. 3C, only the p-channel element region is then covered with a photo resist film 35, and only the dummy gate 25 in the n-channel element region is selectively removed. Thereby, an opening or trench 45A is formed in the insulating film 23.

As shown in FIG. 3D, the photo resist film 35 is then stripped off, and, by oxidation of the substrate or by deposition of an insulating film, a gate insulating film 7A is formed at the bottom portion of the trench 45A. A gate electrode material film 11 for n-channel FET made of the above-mentioned first metal material is further deposited on whole area of the substrate so as to fill up the trench 45A.

As shown in FIG. 4A, the gate electrode material film 11 is then abraded, polished or etched back untill the surface of the insulating film 23 is exposed. Thereby, the gate electrode 11A for n-channel FET is formed.

As shown in FIG. 4B, only the n-channel element region is then covered with a photo resist film 36, and only the dummy gate 26 in the p-channel element region is selectively removed. Thereby, an opening or trench 45B is formed in the insulating film 23.

As shown in FIG. 4C, the photo resist film 36 is then stripped off, and, by oxidation of the substrate or by deposition of an insulating film, a gate insulating film 7B is formed at the bottom portion of the trench 45B. A gate electrode material film 12 for p-channel FET made of the above-mentioned second metal material is further deposited on whole area of the substrate so as to fill up the trench 45B.

As shown in FIG. 4D, the gate electrode material film 12 is then abraded or etched back untill the surface of the insulating film 23 is exposed. Thereby, the gate electrode 12B for p-channel FET is formed.

Thereby, the structure of FIG. 4D is completed. The MISFET 50 is thereafter completed as the complementary integrated circuit through deposition of interlayer insulating films, formation of connection openings reaching the source/drain diffusion layers and the gate electrodes in the interlayer insulating film, and formation of wiring.

In such a specific example, silicon oxide film, polysilicon and silicon oxide film can be utilized in combination as the protection film 21, the film 22 and the insulating film 23, respectively. By using such layered films, it is possible, in the process of removing the dummy gates 25 and 26 in FIG. 3C and FIG. 4B, to first selective remove only the polysilicon 22A or 22B through etching which uses chlorine gas for example and then to remove the thin silicon oxide film 21A or 21B through less damaging etching which uses HF (hydrogen fluoride) for example.

The bottom portions of the trenches 45A and 45B must be subjected to even less damage since they form channels of the FETs. Provision of the protection film 21, that is, 21A and 21B, will fulfil such a requirement.

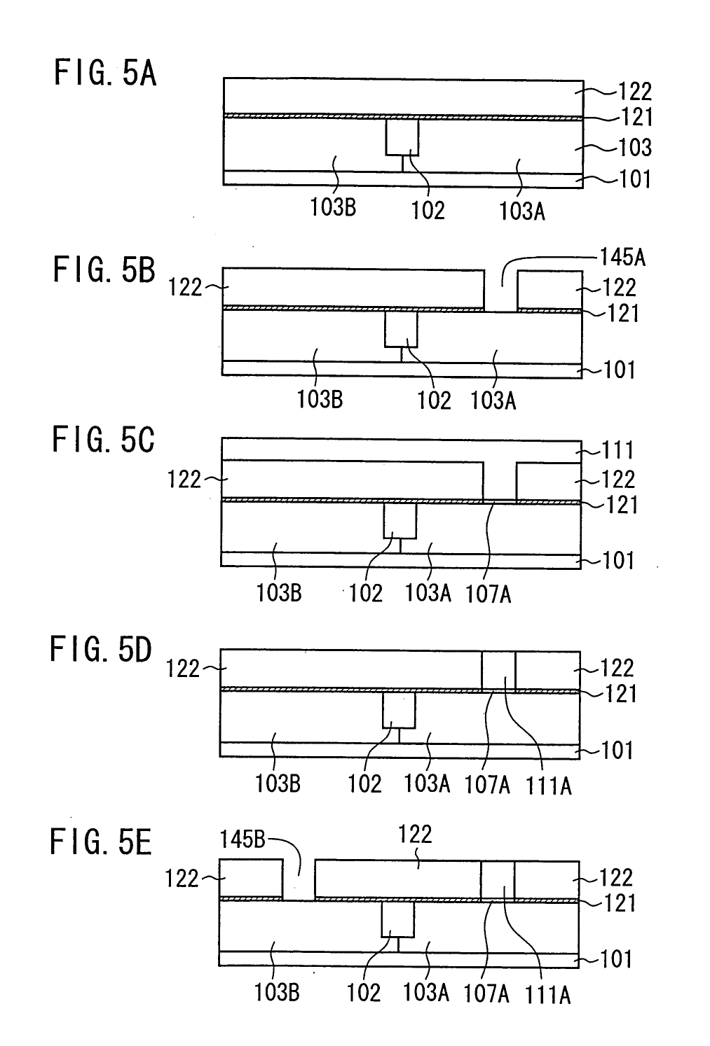

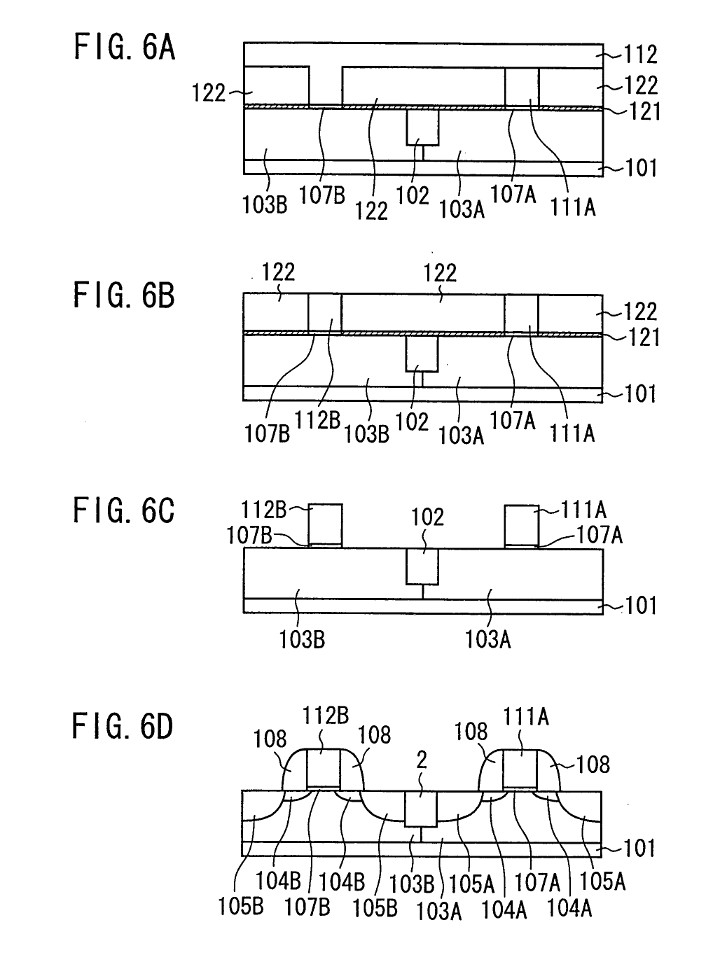

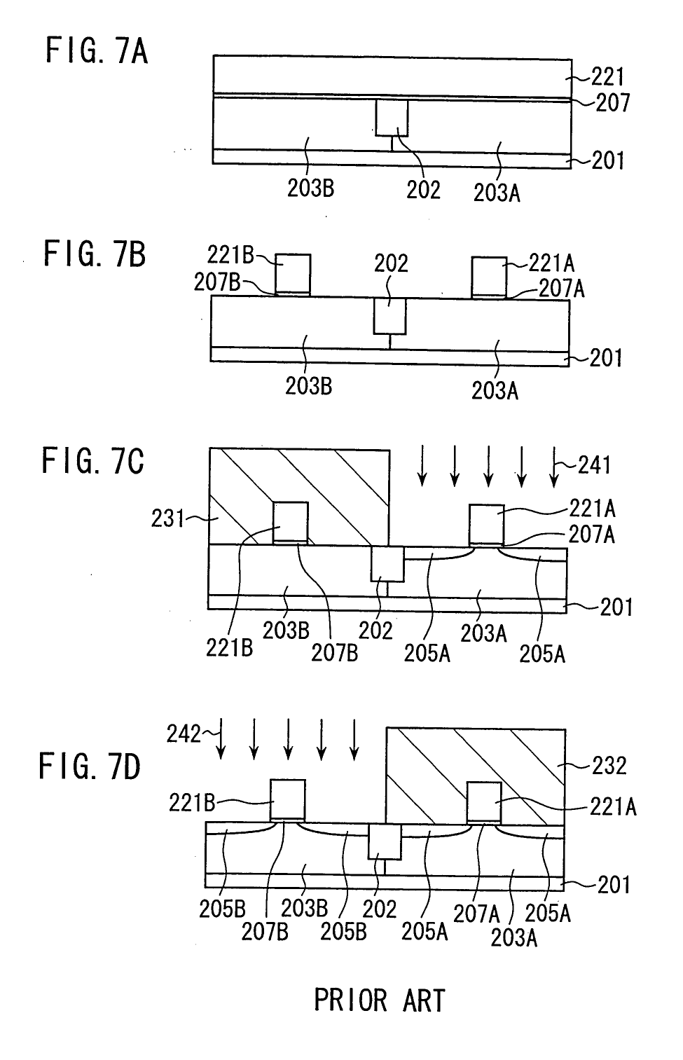

With reference to FIGS. 5A through 5E and FIGS. 6A through 6D, a detailed description will be made on the configuration of another specific example of the complementary integrated circuit and the method of manufacturing the same in accordance with the present invention.

That is, referring to FIGS. 5A through 5E and FIGS. 6A through 6D, there is shown along the manufacturing process cross sections of the complementary MISFET integrated circuit which is another example of the present invention.

In this specific example the source/drain diffusion layers are formed after the formation of the gate electrodes.

First, as shown in FIG. 5A, a p-well 103A, an n-well 103B and an element isolation insulating film 102 are formed on semiconductor layer 103 formed on a semiconductor substrate 101, or on a semiconductor substrate 101 itself in a conventional manner, after which a protection film 121 and a film 122 are deposited in sequence.

The protection film 121 and the film 122 can be for example a silicon nitride film and a silicon oxide film, respectively.

As shown in FIG. 5B, using ordinary photolithography and etching, the protection film 121 and the film 122 are then selectively removed, and an opening or trench 145A is formed at the location where the gate electrode of n-channel FET is to be formed.

Then, as shown in FIG. 5C, a gate insulating film 107A is formed at the bottom portion of the trench 145A by oxidation of the substrate or by deposition of an insulating film, and a film 111 comprising the above-mentioned first metal material for a gate electrode of n-channel FET is deposited thereon so as to fill up the trench 145A.

As shown in FIG. 5D, the film 111 for a gate electrode is then abraded or etched back until the surface of the insulating film 122 becomes exposed. Thereby, the gate electrode 111A for n-channel FET is completed.

As shown in FIG. 5E, using ordinary photolithography and etching, the protection film 121 and the film 122 are then selectively removed, and an opening or trench 145B is formed at the location where the gate electrode of p-channel FET is to be formed.

Then, as shown in FIG. 6A, a gate insulating film 107B is formed at the bottom portion of the trench 145B by oxidation of the substrate or by deposition of an insulating film, and a film 112 comprising the above-mentioned second metal material for a gate electrode of p-channel FET is deposited thereon so as to fill up the trench 145B.

As shown in FIG. 6B, the film 112 for a gate electrode is then abraded or etched back until the surface of the insulating film 122 becomes exposed. Thereby, the gate electrode 112B for p-channel FET is completed.

As shown in FIG. 6C, the remaining films 121 and 122 are then selectively removed by etching.

In case the film 122 is a silicon oxide film, hydrogen fluoride can be used for etching. It is to be noted that if the film 121 is thin, it may remain left.

Afterward, sidewall insulating film spacers 108 are formed, and, by ion implantation and the like, source/drain diffusion layers 4A, 5A, 4B and 5B are formed. These process steps are substantially the same as those mentioned with reference to FIG. 1C through FIG. 2D, and detailed description thereof is omitted here. Thereby, a structure of FIG. 6D is obtained.

The MISFET which is a complementary integrated circuit is thereafter completed through deposition of interlayer insulating films, formation of connection openings reaching the source/drain diffusion layers and the gate electrodes in the interlayer insulating film, and formation of wiring.

In the manufacturing process of the above-mentioned embodiment, the gate electrode 11A or 111A remains buried in the insulating film 23 or 122 during the formation of the subsequently formed gate electrode 12B or 112B. For this reason, the forming step of the gate electrode 12B or 112B will not interfere with the gate electrode 11A or 111A, thus advantageously enabling the two different kinds of gate electrodes to readily and separately be formed on the same substrate.

Furthermore, processing of the gate material films 11 and 12, or 111 and 112 to form the gate electrodes can be effected by abrasion or polishing, for example, chemical mechanical polishing (CMP), mechanical polishing and the like. For this reason, it will be possible even for the materials hard to etch to be processed, thus conveniently providing more choice in the materials used for forming the gate electrodes.

The above embodiment is arranged such that the source/drain diffusion layers 4A and 5A are self-aligned with the gate electrode 11A and that the source/drain diffusion layers 4B and 5B are self-aligned with the gate electrode 12B. Similarly, the source/drain diffusion layers 104A and 105A are self-aligned with the gate electrode 111A and that the source/drain diffusion layers 104B and 105B are self-aligned with the gate electrode 112B. Therefore, the present invention is applicable to any fine MISFETs of 0.1 μm or less.

Usable as the gate electrode material film 11 or 111 for n-channel element is a stable metal such as zirconium or hafnium having an appropriate work function. Alternatively, it is possible to use highly doped n-type polysilicon which is deposited while doping with, e.g., phosphorus or polysilicon doped with, e.g., phosphorus by diffusion from gas source as the gate electrode material film 11 or 111 for n-channel element. Available as the gate electrode material film 12 or 112 for p-channel element is a stable metal, e.g., rhenium having an appropriate work function. Alternatively, it is possible to use highly doped p-type polysilicon which is deposited while doping with boron. In either case, the gate is restrained from becoming depleted as compared with the conventional pn gate configuration, where the gate electrodes are doped by using ion implantation.

The above description has been made with illustration of the case where the gate electrodes consist of a single layer. However, the gate electrodes may be formed of a plurality of layered materials for the purpose of, e.g., reducing the resistance. For example, the lower and upper layers can be made respectively of a material for determining the work function and a material having a low resistance. To this end, the gate electrode material films 11 and 12 of FIG. 3D and FIG. 4C or the gate electrode material films 111 and 112 of FIG. 5C and FIG. 6A may form the laminated films, or multi-layered films.

In such a case, the gate electrode materials of the above description refer to materials at the lowest ends of the gate electrodes, that is, materials at portions in contact with the gate insulating films. This is due to the fact that the work function to determine the characteristics of the FETs is determined by the lowermost layer of the gate electrodes. When that the gate electrodes are composed of the lamination of a plurality of film materials, the n-channel FET and the p-channel FET can include the same gate electrode layers except the lowest ends thereof.

In the above case, the FETs have had the source/drain diffusion layers each consisting of a shallow portion and a deep portion. However, the source/drain diffusion layers can be of a so-called single drain structure having a single depth. In such case, the steps corresponding to FIG. 2A through FIG. 2D can be eliminated.

According to the present invention as set forth hereinabove there is provided a complementary MISFET integrated circuit easy to manufacture and capable of achieving both the miniaturization and enhancement of performances, on the basis of basic configurations ensuring that the miniaturization is facilitated by allowing use of different gate electrode materials for the n-channel element and the p-channel element, that the high performances are secured by restraining the gates from becoming depleted, and that the configuration including a plurality of gate materials can easily be manufactured by employing the manufacturing method in which the gates are buried in the trenches.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative sense rather than a restrictive sense, and all such modifications are to be included within the scope of the present invention. Therefore, it is intended that this invention encompasses all of the variations and modifications as fall within the scope of the appended claims.

What is claimed is:

1. An n-channel field effect transistor having a gate electrode in which at least a portion contacting a gate insulating film is made of a metal material having a work function close to the work function of n-type polysilicon.

2. An n-channel field effect transistor according to claim 1, wherein said metal material consists of a material selected from a group consisting of zirconium and hafnium.

3. An n-channel field effect transistor according to claim 1, wherein at least a portion of said gate electrode in contact with a gate insulating film is made of said metal material, and a portion other than said portion made of said metal material is made of a material having a predetermined low electrical resistivity.

4. A p-channel field effect transistor having a gate electrode in which at least a portion contacting a gate insulating film is made of a metal material having a work function close to the work function of p-type polysilicon.

5. A p-channel field effect transistor according to claim 4, wherein said metal material consists of a material selected from a group consisting of platinum silicide, iridium silicide, cobalt, nickel, rhodium, palladium, rhenium and gold.

6. A p-channel field effect transistor according to claim 4, wherein said metal material consists of rhenium.

7. A p-channel field effect transistor according to claim 4, wherein at least a portion of said gate electrode in contact with a gate insulating film is made of said metal material, and a portion other than said portion made of said metal material is made of a material having a predetermined low electrical resistivity.

8. A complementary integrated circuit comprising:
an n-channel element having a gate electrode in which at least a portion contacting a gate insulating film is made of a first metal material having a work function close to the work function of n-type polysilicon; and
a p-channel element having a gate electrode in which at least a portion contacting a gate insulating film is made of a second metal material having a work function close to the work function of p-type polysilicon.

9. A complementary integrated circuit according to claim 8, wherein said first metal material consists of a material selected from a group consisting of zirconium and hafnium, and said second metal material consists of a material selected from a group consisting of platinum silicide, iridium silicide, cobalt, nickel, rhodium, palladium, rhenium and gold.

10. A complementary integrated circuit according to claim 8, wherein said first metal material consists of a material selected from a group consisting of zirconium and hafnium, and said second metal material consists of rhenium.

11. A complementary integrated circuit according to claim 8, wherein, in said gate electrode of said n-channel element, at least a portion of said gate electrode in contact with a gate insulating film is made of said first metal material, and a portion other than said portion made of said first metal material is made of a material having a predetermined low electrical resistivity, and
wherein, in said gate electrode of said p-channel element, at least a portion of said gate electrode in contact with a gate insulating film is made of said second metal material, and a portion other than said portion made of said second metal material is made of a material having a predetermined low electrical resistivity.

12. A method of manufacturing a complementary integrated circuit, comprising:
preparing a semiconductor substrate;
forming a region for forming an n-channel element and a region for forming a p-channel element on said semiconductor substrate via an element isolation region;
forming a dummy gate electrode in each of said region for forming an n-cannel element and said region for forming a p-channel element;
forming n-type diffusion regions in said region for forming an n-channel element and forming p-type diffusion regions in said region for forming a p-channel element;
forming an insulating film over the entire surface of said semiconductor substrate;
removing said dummy gate formed in one of said region for forming an n-channel element and said region for forming a p-channel element to form a first trench in said insulating film;
filling said first trench with a gate electrode material;
removing said dummy gate formed in the other of said region for forming an n-channel element and said region for forming a p-channel element to form a second trench in said insulating film; and
filling said second trench with a gate electrode material.

13. A method of manufacturing a complementary integrated circuit according to claim 12, wherein, in said forming n-type diffusion regions in said region for forming an n-channel element and forming p-type diffusion regions in said region for forming a p-channel element, an n-type impurity is ion implanted into said region for forming an n-channel element by using a resist film covering said region for forming a p-channel element and said dummy gate formed in said region for forming an n-channel element as a mask, and a p-type impurity is ion implanted into said region for forming a p-channel element by using a resist film covering said region for forming an n-channel element and said dummy gate formed in said region for forming a p-channel element as a mask.

14. A method of manufacturing a complementary integrated circuit according to claim 12, wherein, in said forming an insulating film over the entire surface of said semiconductor substrate, said insulating film is formed so as to cover said dummy gate formed in said region for forming an n-channel element and said dummy gate formed in said region for forming a p-channel element; and said method further comprises, after said forming an insulating film over the entire surface of said semiconductor substrate, removing at least a potion of said insulating film to expose upper surfaces of said dummy gate formed in said region for forming an n-channel element and said dummy gate formed in said region for forming a p-channel element.

15. A method of manufacturing a complementary integrated circuit according to claim 12, wherein said method further comprises, after said removing said dummy gate formed in one of said region for forming an n-channel element and said region for forming a p-channel element to form a first trench in said insulating film, forming a gate insulating film at the bottom portion of said first trench, wherein, in said filling said first trench with a gate electrode material, said first trench is filled with said gate electrode material within said first trench and on said gate insulating film formed at the bottom portion of said first trench,
wherein said method further comprises, after said removing said dummy gate formed in the other of said region for forming an n-channel element and said region for forming a p-channel element to form a second trench in said insulating film, forming a gate insulating film at the bottom portion of said second trench, and wherein, in said filling said second trench with a gate electrode material, said second trench is filled with said gate electrode material within said second trench and on said gate insulating film formed at the bottom portion of said second trench.

16. A method of manufacturing a complementary integrated circuit according to claim 12, wherein, in said filling said first trench with a gate electrode material, a film made of said gate electrode material is formed on whole surface of said semiconductor substrate so as to fill said first trench and is polished to expose the upper surface of said insulating film, and
wherein, in said filling said second trench with a gate electrode material, a film made of said gate electrode material is formed on whole surface of said semiconductor substrate so as to fill said second trench and is polished to expose the upper surface of said insulating film.

17. A method of manufacturing a complementary integrated circuit according to claim 12, wherein a gate electrode material portion filling a trench formed in said region for forming an n-channel element among said first trench and said second trench comprises a metal material which has a work function close to the work function of n-type polysilicon at least at a bottom portion of said gate electrode material portion, and
wherein a gate electrode material portion filling a trench formed in said region for forming a p-channel element among said first trench and said second trench comprises a metal material which has a work function close to the work function of p-type polysilicon at least at a bottom portion of said gate electrode material portion.

18. A method of manufacturing a complementary integrated circuit according to claim 12, wherein a gate electrode material portion filling a trench formed in said region for forming an n-channel element among said first trench and said second trench comprises, at least at a bottom portion thereof, a material selected from a group consisting of zirconium and hafnium, and
wherein a gate electrode material portion filling a trench formed in said region for forming an p-channel element among said first trench and said second trench comprises, at least at a bottom portion thereof, a material selected from a group consisting of platinum silicide, iridium silicide, cobalt, nickel, rhodium, palladium, rhenium and gold.

19. A method of manufacturing a complementary integrated circuit according to claim 12, wherein a gate electrode material portion filling a trench formed in said region for forming an n-channel element among said first trench and said second trench comprises, at least at a bottom portion thereof, n-type polysilicon deposited while doping n-type impurity, and
wherein a gate electrode material portion filling a trench formed in said region for forming a p-channel element among said first trench and said second trench comprises, at least at a bottom portion thereof, p-type polysilicon deposited while doping p-type impurity.

20. A method of manufacturing a complementary integrated circuit according to claim 12, wherein a gate electrode material portion filling a trench formed in said region for forming an n-channel element among said first trench and said second trench comprises, at least at a bottom portion thereof, a material having a work function close to the work function of n-type polysilicon and other portion of said gate electrode material portion comprises a material having a predetermined low electrical resistivity, and
wherein a gate electrode material portion filling a trench formed in said region for forming a p-channel element among said first trench and said second trench comprises, at least at a bottom portion thereof, a material having a work function close to the work function of p-type polysilicon and other portion of said gate electrode material portion comprises a material having a predetermined low electrical resistivity.

21. A method of manufacturing a complementary integrated circuit, comprising:
preparing a semiconductor substrate;
forming a region for forming an n-channel element and a region for forming a p-channel element on said semiconductor substrate via an element isolation region;
forming an insulating film over the entire surface of said semiconductor substrate;
selectively removing said insulating film to form a first trench in said insulating film on one of said region for forming an n-channel element and said region for forming a p-channel element;
filling said first trench with a gate electrode material;
selectively removing said insulating film to form a second trench in said insulating film on the other of said region for forming an n-channel element and said region for forming a p-channel element;
filling said second trench with a gate electrode material;
removing said insulating film;
forming n-type diffusion regions in said region for forming an n-channel element and forming p-type diffusion regions in said region for forming a p-channel element.

22. A method of manufacturing a complementary integrated circuit according to claim 21, wherein said method further comprises, after said selectively removing said insulating film to form a first trench in said insulating film on one of said region for forming an n-channel element and said region for forming a p-channel element, forming a gate insulating film at the bottom portion of said first trench, wherein, in said filling said first trench with a gate electrode material, said first trench is filled with said gate electrode material within said first trench and on said gate insulating film formed at the bottom portion of said first trench,
wherein said method further comprises, after said selectively removing said insulating film to form a second trench in said insulating film on the other of said region for forming an n-channel element and said region for forming a p-channel element, forming a gate insulating film at the bottom portion of said second trench, and wherein, in said filling said second trench with a gate electrode material, said second trench is filled with said gate electrode material within said second trench and on said gate insulating film formed at the bottom portion of said second trench.

23. A method of manufacturing a complementary integrated circuit according to claim 21, wherein, in said filling said first trench with a gate electrode material, a film made of said gate electrode material is formed on whole surface of said semiconductor substrate so as to fill said first trench and is polished to expose the upper surface of said insulating film, and
wherein, in said filling said second trench with a gate electrode material, a film made of said gate electrode material is formed on whole surface of said semiconductor substrate so as to fill said second trench and is polished to expose the upper surface of said insulating film.

24. A method of manufacturing a complementary integrated circuit according to claim 21, wherein a gate electrode material portion filling a trench formed in said region for forming an n-channel element among said first trench and said second trench comprises a metal material which has a work function close to the work function of n-type polysilicon at least at a bottom portion of said gate electrode material portion, and
wherein a gate electrode material portion filling a trench formed in said region for forming a p-channel element among said first trench and said second trench comprises a metal material which has a work function close to the work function of p-type polysilicon at least at a bottom portion of said gate electrode material portion.

25. A method of manufacturing a complementary integrated circuit according to claim 21, wherein a gate electrode material portion filling a trench formed in said region for forming an n-channel element among said first trench and said second trench comprises, at least at a bottom portion thereof, a material selected from a group consisting of zirconium and hafnium, and
wherein a gate electrode material portion filling a trench formed in said region for forming an p-channel element among said first trench and said second trench comprises, at least at a bottom portion thereof, a material selected from a group consisting of platinum silicide, iridium silicide, cobalt, nickel, rhodium, palladium, rhenium and gold.

26. A method of manufacturing a complementary integrated circuit according to claim 21, wherein a gate electrode material portion filling a trench formed in said region for forming an n-channel element among said first trench and said second trench comprises, at least at a bottom portion thereof, n-type polysilicon deposited while doping n-type impurity, and
wherein a gate electrode material portion filling a trench formed in said region for forming a p-channel element among said first trench and said second trench comprises, at least at a bottom portion thereof, p-type polysilicon deposited while doping p-type impurity.

27. A method of manufacturing a complementary integrated circuit according to claim 21, wherein a gate electrode material portion filling a trench formed in said region for forming an n-channel element among said first trench and said second trench comprises, at least at a bottom portion thereof, a material having a work function close to the work function of n-type polysilicon and other portion of said gate electrode material portion comprises a material having a predetermined low electrical resistivity, and
wherein a gate electrode material portion filling a trench formed in said region for forming a p-channel element among said first trench and said second trench comprises, at least at a bottom portion thereof, a material having a work function close to the work function of p-type polysilicon and other portion of said gate electrode material portion comprises a material having a predetermined low electrical resistivity.
